(19) United States
(12) Patent Application Publication
(10) Pub. No.: US 2024/0176245 A1
(43) Pub. Date: May 30, 2024

(54) PHOTOLITHOGRAPHY PATTERNING METHOD

(71) Applicant: KOREA ADVANCED INSTITUTE OF SCIENCE AND TECHNOLOGY, Daejeon (KR)

(72) Inventors: Jungchul SONG, Sejong (KR); Min Jun BAK, Daejeon (KR); Wan-Gyu LEE, Daejeon (KR); Jong-Wan PARK, Daejeon (KR)

(21) Appl. No.: 18/435,960

(22) Filed: Feb. 7, 2024

Related U.S. Application Data
(63) Continuation of application No. PCT/KR2023/008108, filed on Jun. 13, 2023.

(30) Foreign Application Priority Data
Nov. 2, 2022 (KR) 10-2022-0144222

(51) Int. Cl. G03F 7/22; G03F 1/48; G03F 1/80; G03F 1/82; G03F 7/004

(52) U.S. Cl. CPC G03F 7/22; G03F 1/48; G03F 1/80; G03F 1/82; G03F 7/0046

(57) ABSTRACT

A patterning method includes: forming a first photoresist layer on a substrate; performing first divisional exposure on the first photoresist layer with first exposure energy, higher than or equal to threshold energy, using a reticle having lines and spaces of a mask pattern and an exposure apparatus; and shifting the reticle below a line width of the mask pattern and performing second divisional exposure on the first photoresist layer with second exposure energy, higher than or equal to the threshold energy, using the reticle to form a photoresist pattern. A spatial distribution of the first exposure energy may overlap a spatial distribution of the second exposure energy.

### CROSS-REFERENCE TO RELATED APPLICATIONS

This application is a continuation of and claims priority to PCT/KR2023/008108 filed on Jun. 13, 2023, which claims priority to Korea Patent Application No. 10-2022-0144222 filed on Nov. 2, 2022, the entireties of which are both hereby incorporated by reference.

### TECHNICAL FIELD

The present disclosure relates to a photolithography patterning method, and more particularly, to a fine line patterning method to reduce a line width of a photoresist pattern.

### BACKGROUND

Photolithography is technology for transferring a mask pattern of a reticle to a photoresist. A resolution limit of a photoresist pattern depends on a resolution of the reticle and a wavelength of an exposure apparatus.

In typical double patterning, after undergoing a photolithography process in an exposure apparatus, a substrate is unloaded from the exposure apparatus, undergoes a subsequent process, and then reloaded to the exposure apparatus to undergo another photolithography process. Accordingly, a resolution limit of a photoresist pattern may be increased.

### SUMMARY

An aspect of the present disclosure is to increase pattern density beyond the resolution of an exposure apparatus.

Another aspect of the present disclosure is to form a line of about 20 nm and a line pattern of about 20 nm using an ArF immersion apparatus.

A patterning method according to an example embodiment includes: forming a first photoresist layer on a substrate; performing first divisional exposure on the first photoresist layer with first exposure energy, higher than or equal to threshold energy, using a reticle having lines and spaces of a mask pattern and an exposure apparatus; and shifting the reticle below a line width of the mask pattern and performing second divisional exposure on the first photoresist layer with second exposure energy, higher than or equal to the threshold energy, using the reticle to form a photoresist pattern. A spatial distribution of the first exposure energy may overlap a spatial distribution of the second exposure energy.

In an example embodiment, the first exposure energy may be 125% to 155% of threshold energy.

In an example embodiment, a shift value of the reticle may be 10% to 20% of a line width of the mask pattern.

In an example embodiment, the exposure apparatus may be an ArF immersion apparatus, the mask pattern may have a line width of 40 nm, and the mask pattern may have a space width of 40 nm.

In an example embodiment, the patterning method may further include developing the first photoresist layer to form a patterned first photo resist pattern. The first photoresist pattern may have a line width of less than 33 nm.

In an example embodiment, the line width of the patterned first photoresist pattern may be at a level of 20 nm, and a space width of the patterned first photoresist pattern may be at a level of 60 nm.

In an example embodiment, the patterning method may further include developing the first photoresist layer to form a patterned first photoresist pattern. An aspect ratio of a height of the first photoresist pattern to a line width of the first photoresist pattern may be 4 or less.

In an example embodiment, the first exposure energy may be the same as the second exposure energy, and the first exposure energy may be 143% of the threshold energy.

In an example embodiment, the patterning method may further include developing the first photoresist layer to form a patterned first photoresist pattern. The first exposure energy and the second exposure energy may be higher than or equal to the threshold energy, and a sum of the first exposure energy and the second exposure energy may be 260% to 300% of the threshold energy.

A patterning method according to an example embodiment includes: forming a hardmask layer on a substrate; forming a first photoresist layer on the hardmask layer; performing first divisional exposure on the first photoresist layer with first exposure energy, higher than or equal to threshold energy, using a reticle having lines and spaces of a mask pattern and an exposure apparatus; shifting the reticle below the line width of the mask pattern and performing second divisional exposure on the first photoresist layer with second exposure energy, higher than or equal to the threshold energy, using the reticle; developing the first photoresist layer to form a first photoresist pattern; etching the hardmask layer using the first photoresist pattern as a mask to form a preliminary hardmask pattern; removing the first photoresist pattern and then forming a second photoresist layer on the preliminary hardmask pattern; shifting the reticle relative to the preliminary hardmask pattern by ½ of a pitch of the mask pattern and then performing third divisional exposure on the second photoresist layer with third exposure energy, higher than or equal to the threshold energy, using the reticle and the exposure apparatus; and shifting the reticle below the line width of the mask pattern and then performing fourth divisional exposure on the second photoresist layer with fourth exposure energy, higher than or equal to the threshold energy, using the reticle.

In an example embodiment, the patterning method may further include: developing the second photoresist layer to form a second photoresist pattern; and etching the substrate using the second photoresist pattern and the preliminary hardmask pattern as etch masks.

In an example embodiment, the patterning method may further include: developing the second photoresist layer to form a second photoresist pattern; etching the preliminary hardmask pattern using the second photoresist pattern as an etch mask to form a main hardmask pattern; and removing the second photoresist pattern and then etching the substrate using the main hardmask pattern as an etch mask.

### BRIEF DESCRIPTION OF DRAWINGS

The above and other aspects, features, and advantages of the present disclosure will be more clearly understood from the following detailed description, taken in conjunction with the accompanying drawings.

FIG. 1A is a conceptual diagram illustrating a photolithography process with an overdose which does not cause collapse of a photoresist pattern.

FIG. 1B is a conceptual diagram illustrating a photoresist pattern after an exposure process and a development process of FIG. 1A.

FIG. 2A is a conceptual diagram illustrating a photolithography process with overdose energy which causes collapse of a photoresist pattern.

FIG. 2B is a conceptual diagram of the photoresist pattern exposed with exposure energy of 37 mJ in FIG. 2A.

FIG. 2C is a scanning electron microscope (SEM) image illustrating a photoresist pattern exposed with exposure energy of 37 mJ in FIG. 2A.

FIG. 3A is a conceptual diagram illustrating first divisional exposure of micro-shift divisional exposure according to an example embodiment of the present disclosure.

FIG. 3B is a conceptual diagram illustrating second divisional exposure of the micro-shift divisional exposure according to one embodiment of the present invention.

FIG. 3C is a conceptual diagram illustrating first divisional exposure and second divisional exposure of micro-shift divisional exposure according to an example embodiment of the present disclosure.

FIG. 3D is a conceptual diagram illustrating a photoresist pattern formed by the micro-shift divisional exposure of FIG. 3C.

FIG. 4 is a scanning electron microscope (SEM) image of micro-shift divisional exposure according to an example embodiment of the present disclosure.

FIG. 5 is a diagram illustrating divisional exposure energy and micro-shift amount of the micro-shift divisional exposure according to an example embodiment of the present disclosure.

FIG. 6A is a CD-SEM image of FIG. 4.

FIG. 6B is an enlarged SEM image of FIG. 4.

FIG. 7 is SEM images illustrating patterning results depending on a thickness of a photoresist layer according to an example embodiment of the present disclosure.

FIGS. 8A to 8G are diagrams illustrating a double patterning method according to an example embodiment of the present disclosure.

FIGS. 9A to 9H are diagrams illustrating a double patterning method according to an example embodiment of the present disclosure.

### DETAILED DESCRIPTION

A method for increasing pattern density is required due to process limitations of single patterning. Single patterning is limited in the pitch of patterns due to the resolution limit of a photoresist pattern. Multi-patterning is a method for increasing pattern density, and includes LLE (Litho-Litho-Etch) technique to perform exposure twice, LELE (Litho-Etch-Litho-Etch) technique to perform exposure and etching twice using a hardmask, and SASP (Self-Aligned Double Patterning) technique using a sidewall spacer.

In the LLE (Litho-Litho-Etch) technique, first patterning and exposure is performed using a mask pattern having different line widths and space widths and a predetermined pitch, the mask pattern is shifted by a distance of pitch/2, and second patterning and exposure is then performed. Thus, fine patterns may be implemented. The first patterning exposure does not spatially overlap the second patterning exposure.

According to an example embodiment, when divisional exposures are performed using a mask pattern having the same line width and space width before and after first micro-shift, an undercut-suppressed photoresist pattern may be formed. The first partial exposure before the micro-shift can form a photoresist preliminary pattern on the photoresist. The micro-shift may be at the level of 1/10 of the line width of the mask pattern. The second divisional exposure after the micro-shift may form a first photoresist pattern by overlapping a preliminary photoresist pattern. The first and second divisional exposures may divide over-dose expose energy above threshold energy. An energy spatial distribution of the first divisional exposure may spatially overlap an energy spatial distribution of the second divisional exposure due to the amount of micro-shift. Accordingly, a maximum of the energy spatial distribution of the first divisional exposure and a maximum of the energy spatial distribution of the second divisional exposure may be spaced apart from each other by the amount of micro-shift. The energy spatial distribution of the first divisional exposure and the energy spatial distribution of the second divisional exposure may form a composite energy spatial distribution. The photoresist layer may be activated in response to the composite energy spatial distribution. As a result, the composite energy spatial distribution may form various forms of energy spatial distributions, suppress undercut caused by light reflection from a lower portion of the photoresist layer, and contribute to the activation of the photoresist layer.

Micro-shift divisional exposure according to an example embodiment may suppress collapse of a photoresist pattern to form a fine pattern.

The micro-shift divisional exposure according to the present disclosure may be applied to the LLE (Litho-Lithi-Etch) technique, the LELE (Litho-Etch-Litho-Etch) technique of performing exposure and etching twice using a hardmask, and the SASP (Self-Aligned Double Patterning) technique using a sidewall spacer. Accordingly, multi-patterning may be performed.

Hereinafter, example embodiments will now be described more fully with reference to the accompanying drawings, in which some example embodiments are shown. Example embodiments may, however, be embodied in many different forms and should not be construed as being limited to the embodiments set forth herein. Rather, these example embodiments are provided so that this disclosure will be thorough and complete, and will fully convey the scope of example embodiments of the present disclosure to those of ordinary skill in the art. In the drawings, the thicknesses of layers and regions are exaggerated for clarity. Like reference characters and/or numerals in the drawings denote like elements.

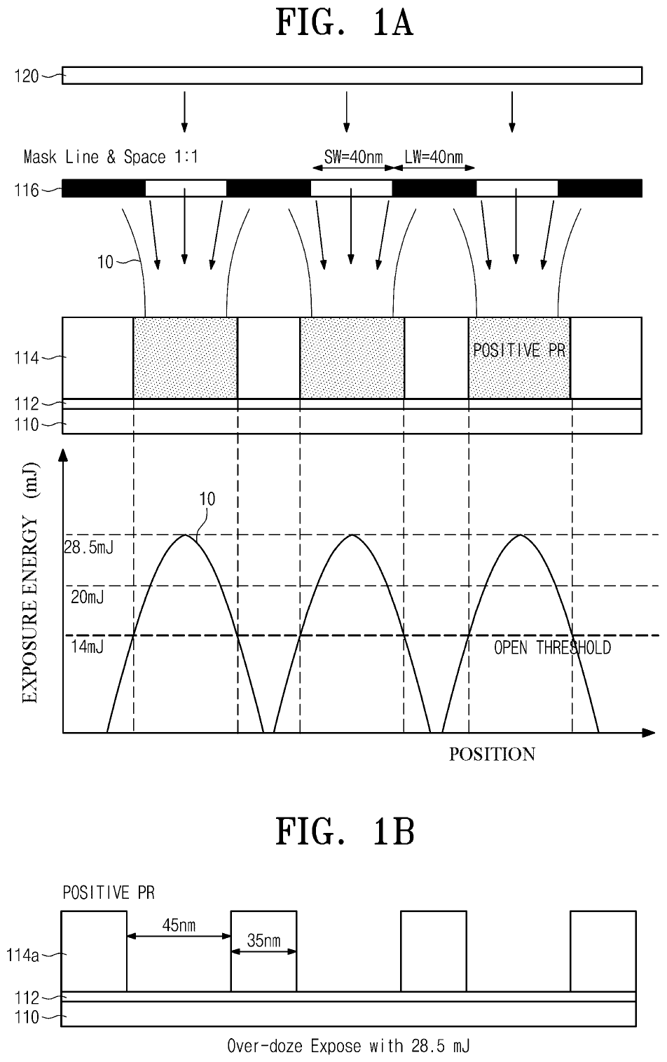

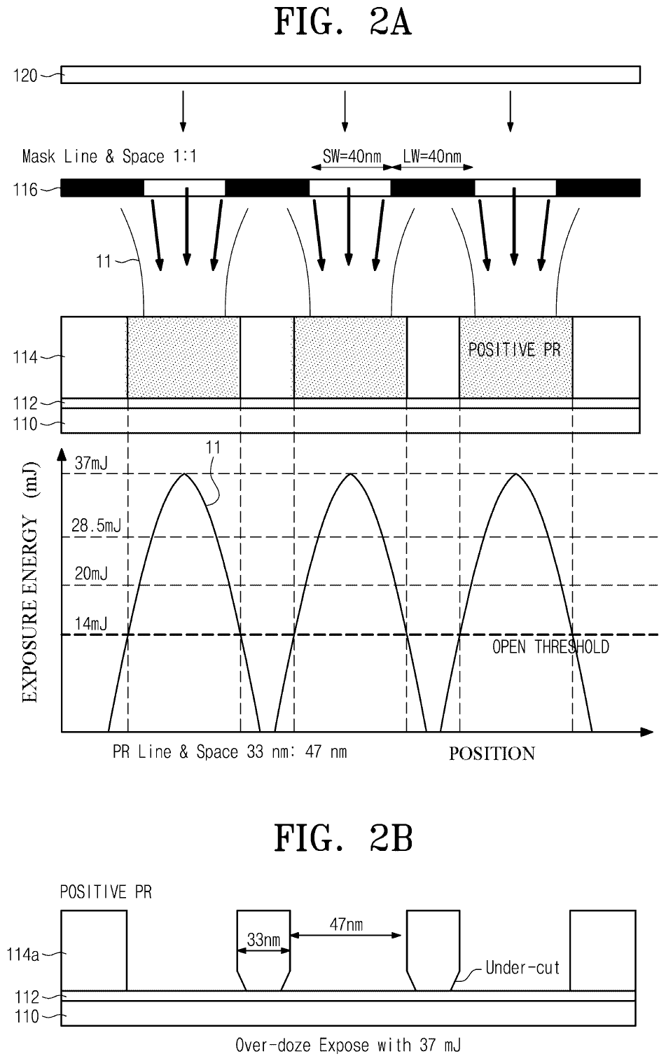

FIG. 1A is a conceptual diagram illustrating a photolithography process with an overdose which does not cause collapse of a photoresist pattern.

FIG. 1B is a conceptual diagram illustrating a photoresist pattern after an exposure process and a development process of FIG. 1A.

Referring to FIGS. 1A and 1B, a bottom anti-reflect coating (BARC) 112 may be coated on a substrate 110, and a photoresist layer 114 may be formed on the bottom anti-reflect coating 112. Single exposure to a positive photoresist may cause a region irradiated with energy above the open threshold energy to be a space region after development, and may cause a region irradiated with energy below the open threshold energy to be a line region after the development.

A line width LW and a space width SW of a mask pattern of a reticle 116 may each be 40 nm. Accordingly, the pitch of the mask pattern may be 80 nm. Threshold exposure energy of the exposure apparatus 120 may be 14 mJ. For example, when the exposure energy of the exposure apparatus 120 is 20 mJ, the line width and space width of the photoresist pattern 114a may each be 40 nm. When the line width of the mask pattern and the line width of the photoresist pattern are the same, the exposure energy (20 mJ) may be the optimal energy.

Referring to FIG. 1A, when exposure energy 10 of the exposure apparatus 120 is 28.5 mJ, a line width of the photoresist pattern 114a may be about 35 nm and a space width may be about 45 nm. In the energy spatial distribution, energy exceeding the threshold energy may be partially compensated for in the bottom anti-reflect coating 112 but may affect a side surface of the photoresist pattern.

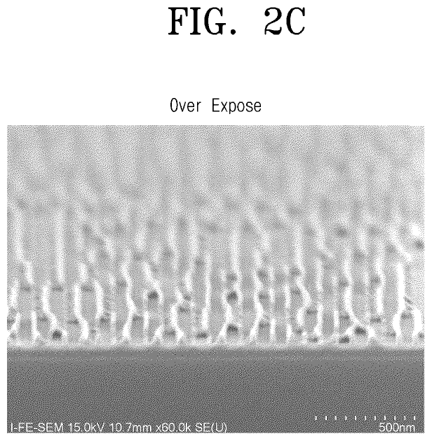

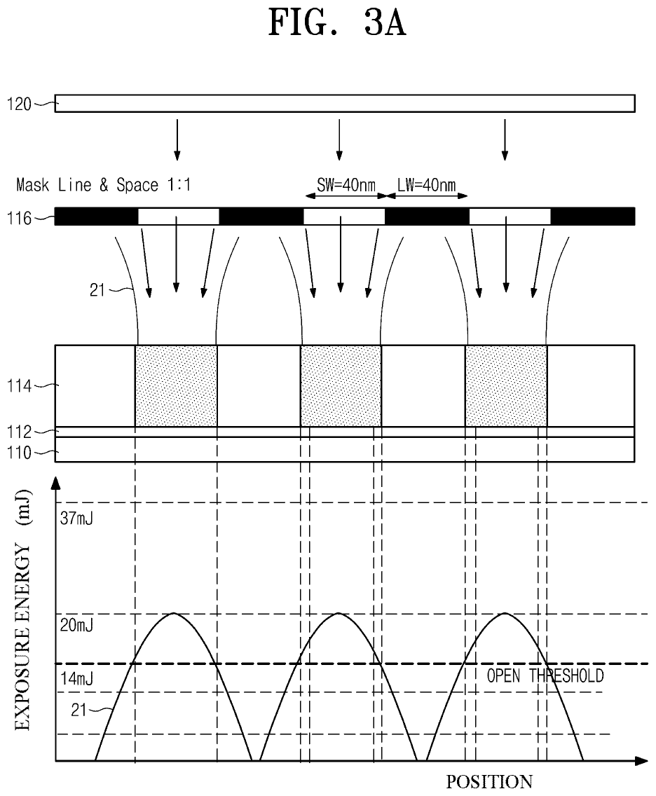

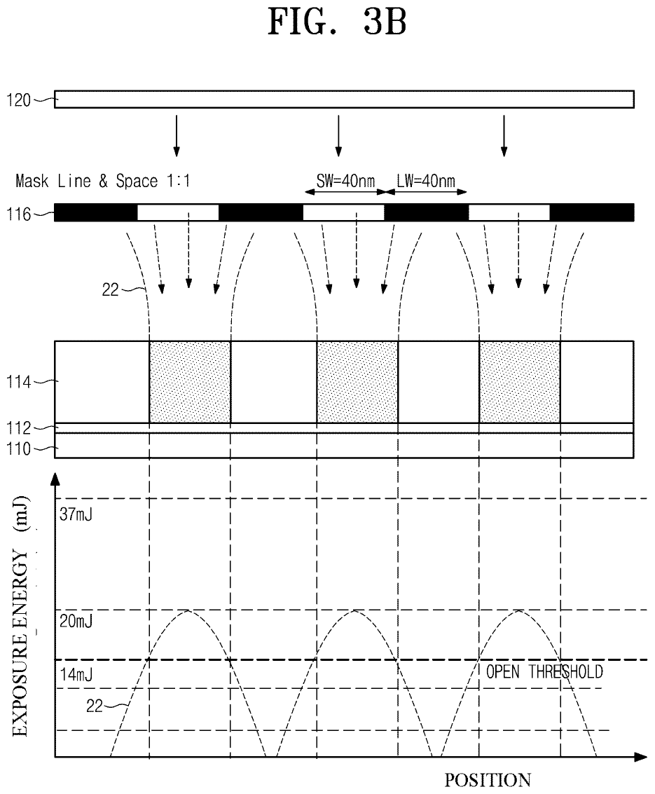

FIG. 2A is a conceptual diagram illustrating a photolithography process with overdose energy which causes collapse of a photoresist pattern.

FIG. 2B is a conceptual diagram of the photoresist pattern exposed with exposure energy of 37 mJ in FIG. 2A.

FIG. 2C is a scanning electron microscope (SEM) image illustrating a photoresist pattern exposed with exposure energy of 37 mJ in FIG. 2A.

Referring to FIGS. 2A, 2B, and 2C, a bottom anti-reflect coating (BARC) 112 may be coated on a substrate 110, and a photoresist layer 114 may be formed on the bottom anti-reflect coating 112.

A line width and a space width of a mask pattern of a reticle 120 are each 40 nm. Therefore, a pitch of the mask pattern is 80 nm. Threshold exposure energy of the exposure apparatus 200 may be 14 mJ. When the exposure energy 11 of the exposure device is 37 mJ, a line width and a space width of the photoresist pattern 114a are 33 nm and 47 nm, respectively. When the exposure energy is 37 mJ or more, energy reflected from the bottom anti-reflect coating 112 may increase the energy in a lower end portion of the photoresist pattern 114a and a bottom of the photoresist pattern may be cut off, causing a lower portion of the photoresist pattern to be tilted or torn. Accordingly, the photoresist pattern 114a may collapse with an undercut, or may be torn to disappear.

For example, the exposure energy may be excessively provided to a level of 37 mJ, exceeding the optimal energy of 20 mJ. In this case, based on the line width of the mask pattern of 40 nm, the exposure energy of 37 mJ may reduce the line width of the photoresist pattern 114a to 33 nm. However, when the exposure energy is greater than 37 mJ, the photoresist pattern 114a may collapse due to undercut on a lower side surface after development.

When the exposure energy exceeds the optimal energy, an overdose energy process may only implement a line width of 33 nm for the photoresist pattern, based on the line width and space width of the 40 nm mask pattern. This is because the amount of energy reflected from the bottom anti-reflect coating 112 is large. The reflected energy cuts off a lower portion of the bottom anti-reflect coating 112, so that the photoresist pattern 114a is unable to stand vertically.

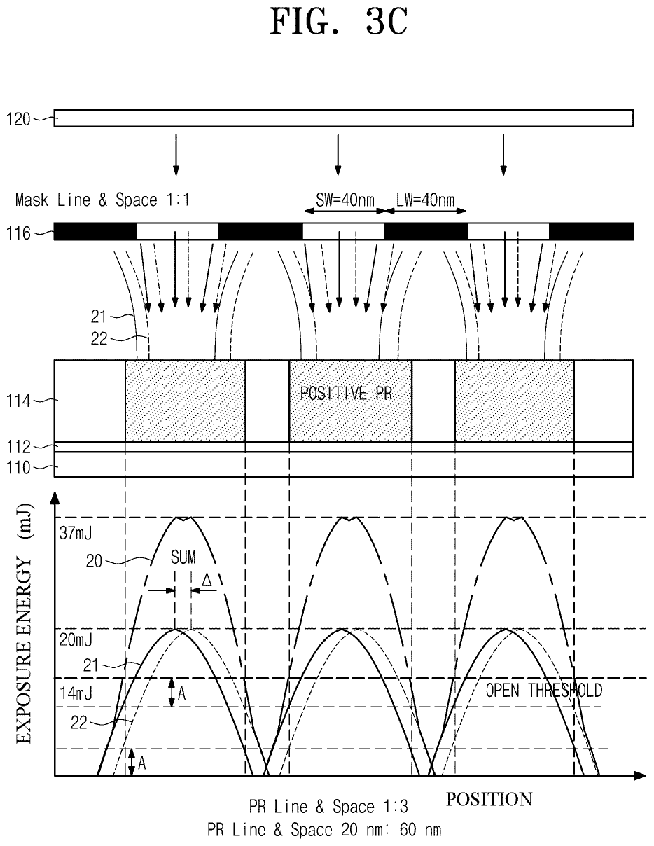

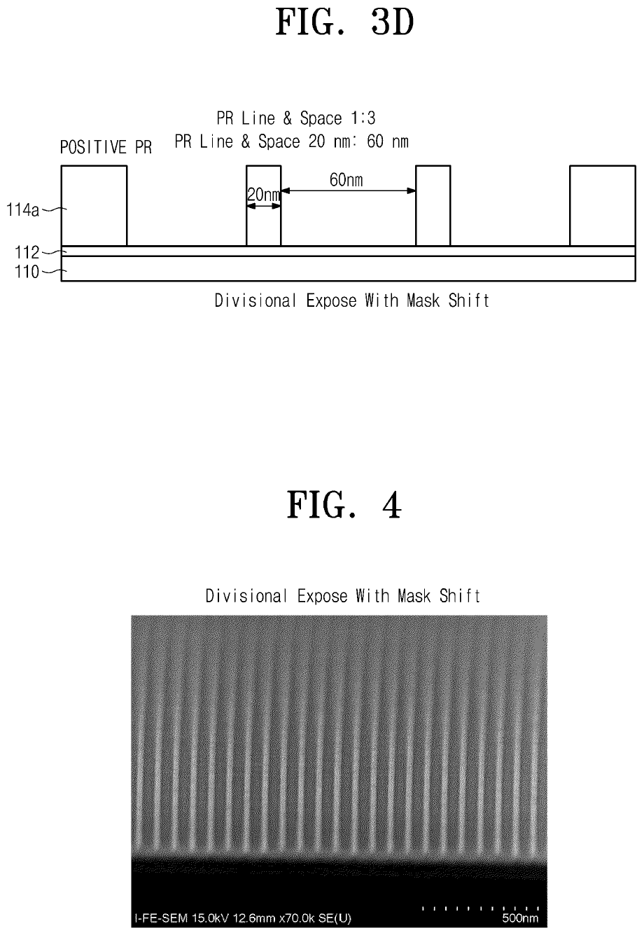

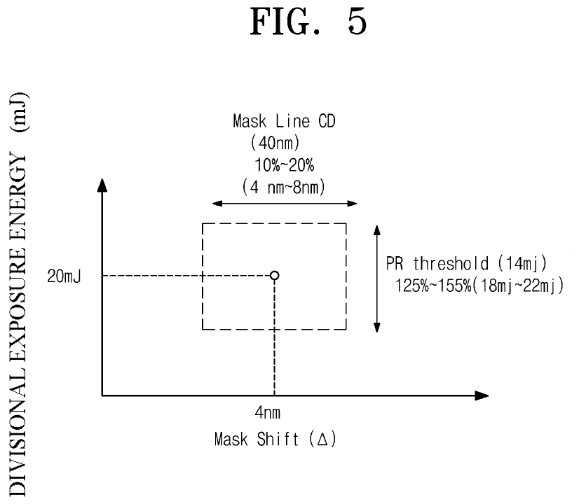

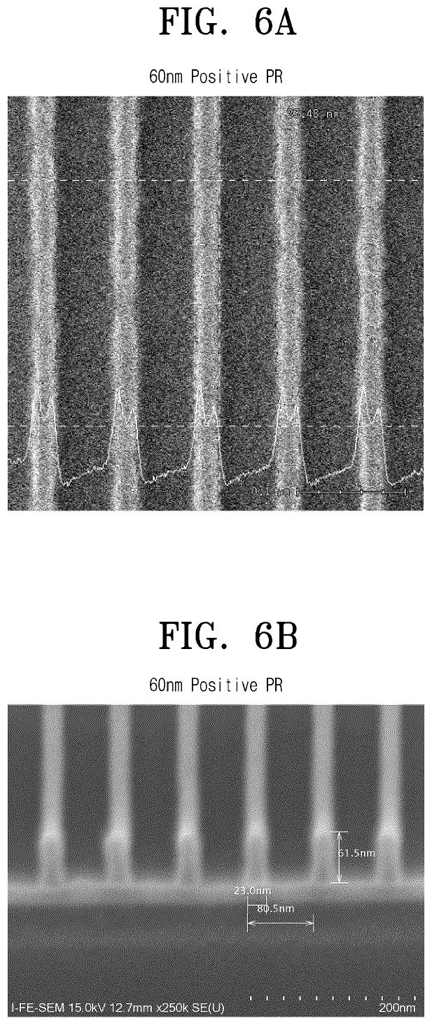

FIG. 3A is a conceptual diagram illustrating first divisional exposure of micro-shift divisional exposure according to an example embodiment of the present disclosure.

FIG. 3B is a conceptual diagram illustrating second divisional exposure of the micro-shift divisional exposure according to one embodiment of the present invention.

FIG. 3C is a conceptual diagram illustrating first divisional exposure and second divisional exposure of micro-shift divisional exposure according to an example embodiment of the present disclosure.

FIG. 3D is a conceptual diagram illustrating a photoresist pattern formed by the micro-shift divisional exposure of FIG. 3C.

Referring to FIGS. 3A to 3D, a patterning method according to an example embodiment may include forming a first photoresist layer 114 on a substrate 110; performing first divisional exposure on the first photoresist layer 114 with first exposure energy 21, higher than or equal to threshold energy, using a reticle 116 having lines and spaces of a mask pattern and an exposure apparatus 120; and shifting the reticle 116 below a line width LW of the mask pattern and performing second divisional exposure on the first photoresist layer 114 with second exposure energy 22, higher than or equal to the threshold energy, using the reticle 116.

The exposure apparatus 120 may be an ArF immersion apparatus, a KrF apparatus, or an EUV apparatus. A wavelength of the ArF immersion apparatus may be 193 nm.

In the reticle 116, a ratio of a size of the photoresist pattern 114a to a size of the mask pattern of the reticle may be 1:1 to 1:10. The reticle 112 may have lines and spaces of a mask pattern, and a line-to-space width ratio may be 1:1. For example, a line width LW of the mask pattern may be 40 nm, and a space width SW of the mask pattern may be 40 nm.

The substrate 110 may be a semiconductor substrate. The substrate may include an etch layer for etching.

A bottom anti-reflect coating (BARC) 112 may be disposed on the substrate 110. The bottom anti-reflect coating 112 may be disposed below the first photoresist layer 114 to reduce reflection of exposure beam.

The first photoresist layer 114 may be a positive photoresist or a negative photoresist. A thickness of the first photoresist layer 114 may be 50 nm to 90 nm.

The substrate 110 coated with the first photoresist layer 114 may be loaded into the exposure apparatus, and may then be aligned with the reticle 116.

First divisional exposure may be performed on the first photoresist layer 114 with first exposure energy 21, higher than or equal to the threshold energy, using the reticle 116 with the lines and spaces of the mask pattern and the exposure apparatus 120. The threshold energy may be 14 mJ in ArF immersion apparatus and the first photoresist layer 114. The first exposure energy 21 may be 20 mJ. At an exposure energy of 20 mJ, a ratio of the line width of the photoresist pattern to the line width of the mask pattern of the reticle may be 1:1.

The first exposure energy 21 may be 125 percent to 155 percent of the threshold energy (14 mJ). The photoresist layer exposed to the first exposure energy 21, higher than or equal to the threshold energy of 14 mJ, may be chemically changed and activated.

After the first divisional exposure is performed, the reticle may be micro-shifted below the line width of the mask pattern. The shift value (A) of the reticle may be 10 to 20 percent of the line width (LW=40 nm) of the mask pattern. For example, when the line width of the mask pattern is 40 nm, the shift value (A) of the reticle may be 4 nm.

After the reticle is micro-shifted, second divisional exposure may be performed on the first photoresist layer 114 using the reticle with second exposure energy 22, higher than or equal to the threshold energy. The second exposure energy 22 of the second divisional exposure may be 125 percent to 155 percent of the threshold energy. For example, the second exposure energy 22 may be 20 mJ.

Referring to FIG. 3C, a spatial distribution of the first exposure energy 21 of the first divisional exposure and a spatial distribution of the second exposure energy 22 of the second divisional exposure are represented. In addition, the sum 20 of the spatial distribution of the first exposure energy and the spatial distribution of the second exposure energy is represented. A maximum of the sum may be at the level of 37 mJ. Even when there is a time difference between the first divisional exposure and the second divisional exposure, a chemical reaction of the photoresist may be accumulated.

In the micro-shift divisional exposure according to the present disclosure, the photoresist layer may not be activated when the sum of exposure energies is less than the threshold energy (14 mJ). According to experimental results, micro-shift divisional exposure may form a photoresist pattern with less damage to a lower end of the bottom anti-reflect coating 112 by adjusting the amount of reflection of exposed light. Accordingly, an inclined shape of the lower end of the photoresist pattern may be suppressed. The optimal micro-shift amount (Δ) of the reticle may be 10 to 20% of the line width (LW) of the mask pattern. The first exposure energy 21 and the second exposure energy 22 may be higher than or equal to the threshold energy, and the sum of the first exposure energy 21 and the second exposure energy 22 may be 260 percent to 300 percent of the threshold energy.

Energy insufficient in the first divisional exposure may be added to the energy of the second divisional exposure to activate the photoresist layer. However, energy reflected in the first divisional exposure may not be added to energy reflected in the second divisional exposure. The micro-shift divisional exposure method may control exposure energy and energy spatial distribution more precisely than single overexposure. The reflected energy reduced in micro-shift divisional exposure may suppress the collapse of the photoresist pattern. Accordingly, a minimum line width may be reduced to 20 nm, compared to 33 nm that is a minimum line width which can be achieved by single overexposure. When the line width of the mask pattern is 40 nm and the space width is 40 nm, a line width of the photoresist pattern 114a may be 20 nm and a space width may be 60 nm. The line-to-space width ratio of the photoresist pattern 114a may be 1:3.

According to a modified embodiment, micro-shift 3-divisional exposure may be applied. For example, the micro-shift 3-divisional exposure may include first divisional exposure, first micro-shift of a reticle, second divisional exposure, second micro-shift of the reticle, and third divisional exposure. Energies for the first divisional exposure, the second divisional exposure, and the third divisional exposure may be the same.

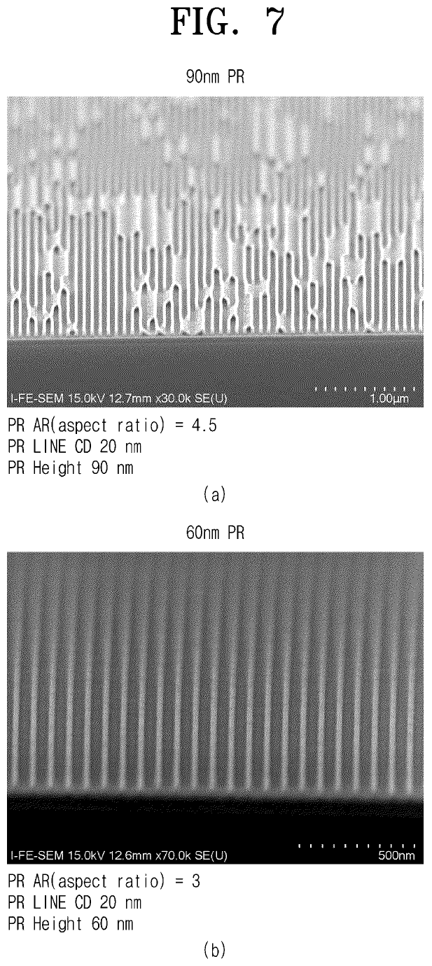

FIG. 4 is a scanning electron microscope (SEM) image of micro-shift divisional exposure according to an example embodiment of the present disclosure.

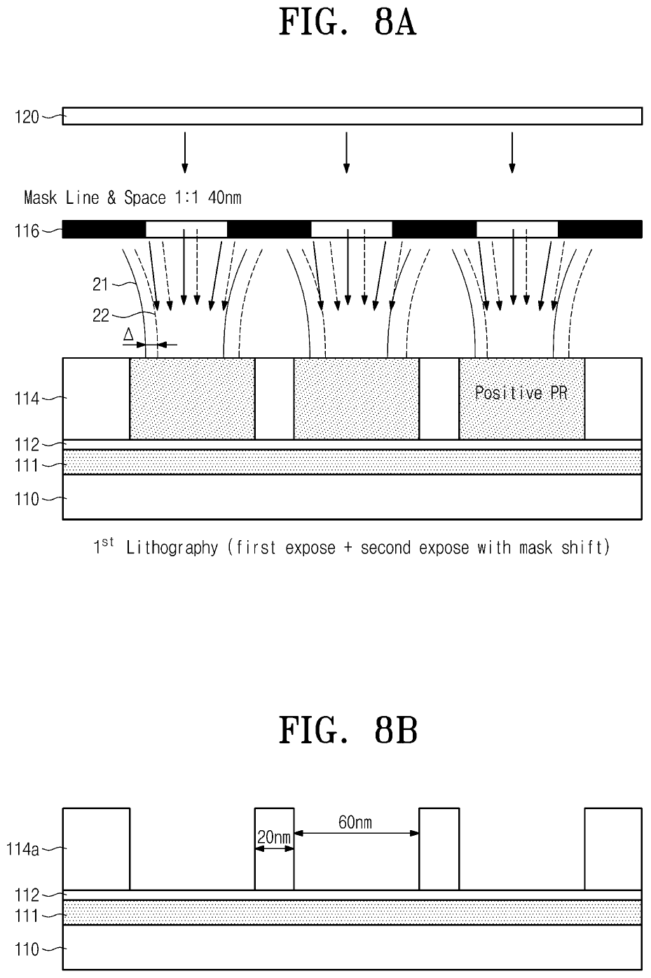

FIG. 5 is a diagram illustrating divisional exposure energy and micro-shift amount of the micro-shift divisional exposure according to an example embodiment of the present disclosure.

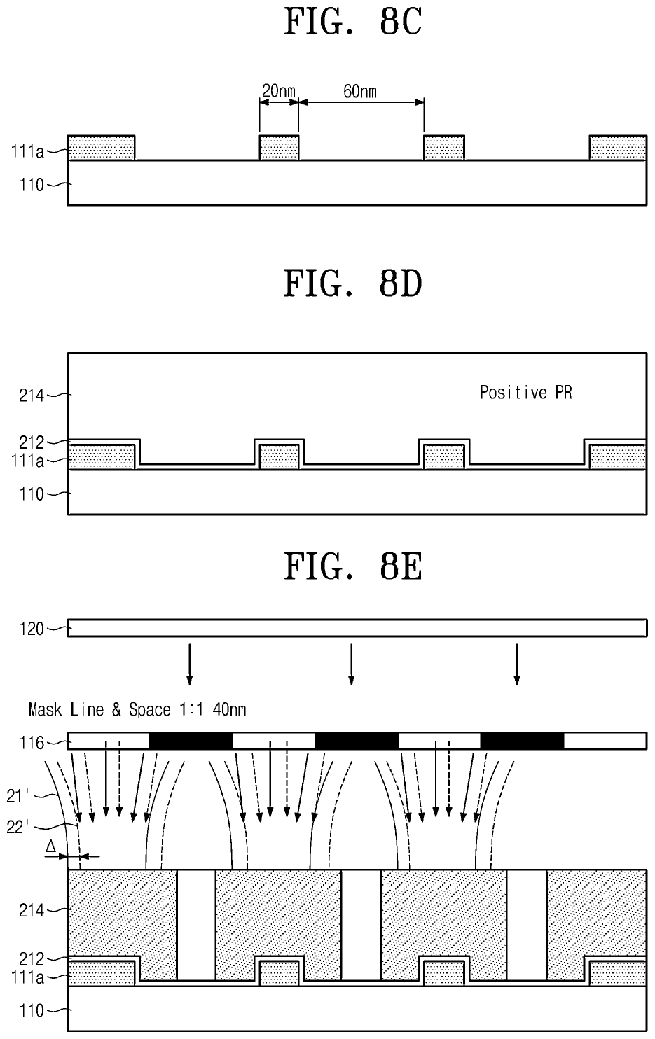

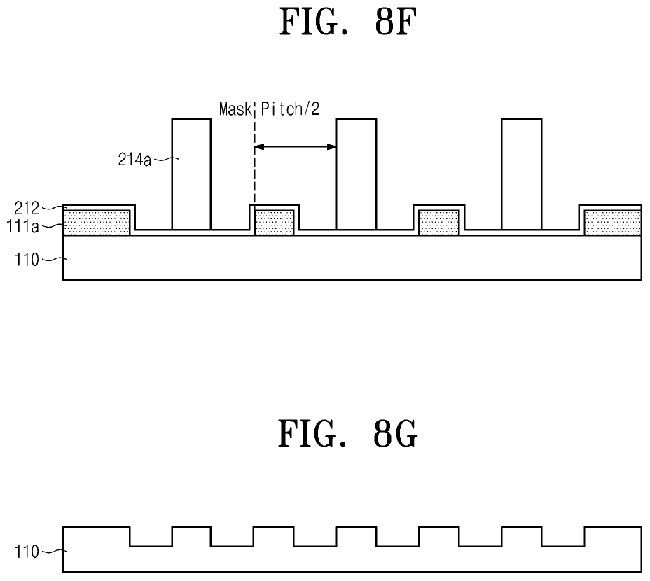

FIG. 6A is a CD-SEM image of FIG. 4.

FIG. 6B is an enlarged SEM image of FIG. 4.

Referring to FIGS. 4 and 5, exposure energy 21 or 22 of first divisional exposure or second divisional exposure may be at the level of 125% to 155% (18 mJ to 22 mJ) of photoresist opening threshold energy (14 mJ). A shift value of the mask pattern or the reticle may be 10% to 20% (4 nm to 8 nm) of the line width (40 nm) of the mask pattern.

In the present experiment, an ArF immersion apparatus was used. A thickness of the photoresist layer is 60 nm, an illumination system is Dipole 35 Y, and a numerical aperture (NA) is 1.35. A micro-shift value (A) of a mask is 4 nm. A line width of a reticule mask pattern is 40 nm, and a space width of the reticle mask pattern is 40 nm. Exposure energy of the first divisional exposure 21 is 20 mJ, and exposure energy of the second divisional exposure 22 is 20 mJ. A line width of the photoresist pattern is 23 nm, a height of the photoresist pattern is 61.5 nm, and a pitch of the photoresist pattern is 80.5 nm.

In an ArF exposure apparatus, to form fine patterns of 33 nm or less, the present disclosure proposes a micro-shift divisional exposure technology. A position of a mask pattern on a reticle may be vertically shifted to be perpendicular to a line-extension direction while a wafer is fixed, so that exposure energy may be divided before and after the micro-shift and then divisionally exposed to form a fine pattern. For example, the total exposure energy may be divided into first exposure energy 21 and second exposure energy 22, based on time. In addition, a spatial distribution of the first exposure energy 21 and a spatial distribution of the second exposure energy 22 may overlap each other due to the micro-shift value (A). To this end, a substrate 110 and a reticle 116 may be mounted a stage of the exposure apparatus. The reticle 116 may be exposed once before and after a fine change in coordinates of the reticle 116. Thus, exposure may be performed without overlay error. The micro-shift divisional exposure may suppress the collapse of photoresist patterns.

In an example embodiment, micro-shift divisional exposure (or micro-shift multiple exposure) may select exposure energy of overexposure conditions in which the photoresist pattern collapses. When single exposure is performed using the exposure energy of the overexposure conditions, the photoresist pattern may collapse. For example, the exposure energy of the overexposure conditions may be 37 mJ or more. The exposure energy of the overexposure conditions may be divided into two exposure energies based on time, and the divided exposure energies may spatially overlap each other. A maximum of the spatial distribution of the summed exposure energy may be 37 mJ or more. The spatial distribution of the summed exposure energy may be different from the spatial distribution of the overexposure conditions. In addition, micro-shift divisional exposure may change an energy distribution of reflected light.

According to experimental results, the photoresist pattern collapses in single exposure of 37 mJ or more, but may not collapse in the micro-shift divisional exposure.

First divisional exposure is performed on the photoresist layer, and second divisional exposure is then performed without unloading a wafer from the exposure apparatus after micro-shifting mask coordinates.

Based on characteristics of the photoresist according to the present disclosure, a pattern having a line width of 20 nm may be implemented using an ArF immersion process. A resolution limit of the ArF immersion process may be 38 nm. The patterning method according to the present disclosure may implement 20 nm patterns below the resolution limit of the ArF immersion process.

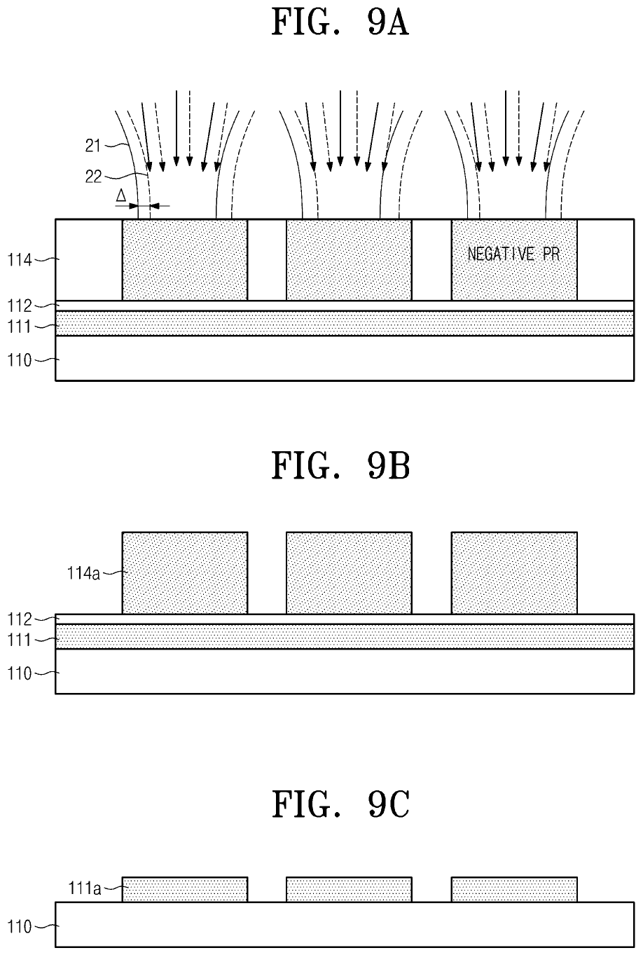

FIG. 7 is SEM images illustrating patterning results depending on a thickness of a photoresist layer according to an example embodiment of the present disclosure.

Referring to FIG. 7, (a) illustrates the case in which a photoresist layer 114 has a height of 90 nm, (b) illustrates the case in which a photoresist layer 114 has a height of 60 nm. Process conditions are the same as those of FIG. 4, other than a thickness of a photoresist layer.

In the in which the photoresist layer 114 has a height of 90 nm, an aspect ratio is 4.5 and pattern collapse is locally found after development is performed using a spin development method. However, in the case in which the photoresist layer 114 has a height of 60 nm, an aspect ratio is 3 and pattern collapse is not found after development is performed using the spin development method. The aspect ratio is a value obtained by dividing the height of the photoresist layer 114 by a line width (20 nm).

Therefore, the height of the photoresist needs to be reduced to 90 nm or less to reduce the aspect ratio. For example, the aspect ratio may be 4 or less.

When the photoresist has a thickness of 90 nm, a line width may be 23 nm. When the photoresist has a thickness of 60 nm, a line width may be 21 nm. The thickness of the photoresist may be reduced to achieve a line width of 20 nm or less.

In addition, when the development method changes from the spin development method to the stop method, patterning may be performed even at a thickness of 90 nm.

The micro-shift divisional exposure according the present disclosure may be applied to a double patterning process using an LELE process.

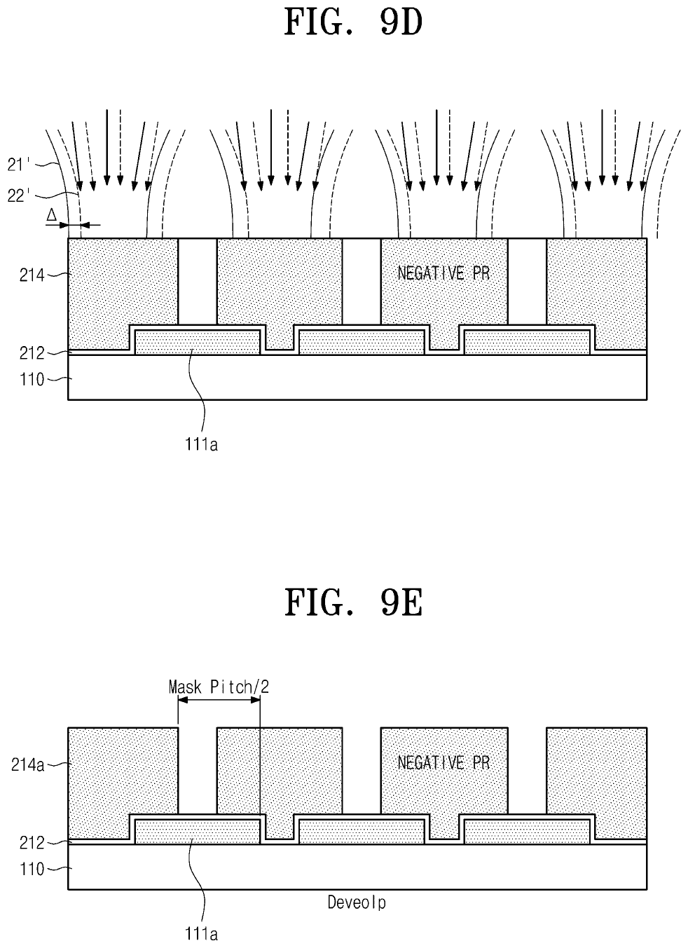

FIGS. 8A to 8G are diagrams illustrating a double patterning method according to an example embodiment of the present disclosure.

Referring to FIGS. 8A to 8G, a double patterning method according to an example embodiment may include forming a hardmask layer 111 on a substrate 110; forming a first photoresist layer 114 on the hardmask layer 111; performing first divisional exposure on the first photoresist layer 114 with first exposure energy 21, higher than or equal to threshold energy, using a reticle 116 having lines and spaces of a mask pattern and an exposure apparatus 120; shifting the reticle below the line width of the mask pattern and performing second divisional exposure on the first photoresist layer 114 with second exposure energy, higher than or equal to the threshold energy, using the reticle; developing the first photoresist layer 114s to form a first photoresist pattern 114a; etching the hardmask layer 111 using the first photoresist pattern 114a as a mask to form a preliminary hardmask pattern 111a; removing the first photoresist pattern 114a and then forming a second photoresist layer 214 on the preliminary hardmask pattern 111a; shifting the reticle relative to the preliminary hardmask pattern 111a by ½ of a pitch of the mask pattern and then performing third divisional exposure on the second photoresist layer 214 with third exposure energy, higher than or equal to the threshold energy, using the reticle 116 and the exposure apparatus 120; and shifting the reticle below the line width of the mask pattern and then performing fourth divisional exposure on the second photoresist layer 214 with fourth exposure energy, higher than or equal to the threshold energy, using the reticle.

Referring to FIG. 8A, a substrate 110 may be a semiconductor substrate. The substrate may include an etch layer for etching. A hardmask layer 111 may be formed on the substrate. The hardmask layer 111 may be an amorphous carbon layer.

A bottom anti-reflect coating (BARC) 112 may be formed on the hardmask layer. The bottom anti-reflect coating 112 may be disposed below the first photoresist layer 114 to reduce reflection of exposure beam.

A first photoresist layer 114 may be formed on the bottom anti-reflect coating 112. The first photoresist layer 114 may be a positive photoresist. The first photoresist layer 114 may have a thickness of 50 nm to 90 nm.

First divisional exposure may be performed on the first photoresist layer 114 with the first exposure energy 21, higher than or equal to threshold energy, using the reticle 116 having lines and spaces of the mask pattern and the exposure apparatus 120.

The reticle may be moved below the line width of the mask pattern, and second divisional exposure may be performed on the first photoresist layer using the reticle with second exposure energy, higher than or equal to the threshold energy. A shift value (A) of the reticle may be 10% to 20% (4 nm to 8 nm) of a line width (40 nm) of the mask pattern.

Referring to FIG. 8B, the first photoresist layer may be developed to form a first photoresist pattern 114a. The development process may use a spin development apparatus.

Referring to FIG. 8C, the hardmask layer 111 may be etched using the first photoresist pattern 114a as an etch mask to form a preliminary hard mask pattern 111a. The etching may be performed in an anisotropic plasma etching apparatus.

Referring to FIG. 8D, the first photoresist pattern 114a may be removed, and a second photoresist layer 214 may then be formed on the preliminary hard mask pattern 111a. A bottom reflective coating layer 212 may be disposed below the second photoresist layer 214. The second photoresist layer 214 may be formed of the same material and structure as the first photoresist layer 114.

Referring to FIG. 8E, the reticle 116 may be shifted by ½ of a pitch of the mask pattern with respect to the preliminary hardmask pattern 111a, and third divisional exposure may then be performed on the second photoresist layer 214 with third exposure energy 21′, higher than or equal to the threshold energy, using the reticle 116 and the exposure apparatus 120.

The reticle 216 may be shifted below the line width of the mask pattern, and fourth divisional exposure may then be performed on the second photoresist layer 241 with fourth exposure energy 22′, higher than or equal to the threshold energy, using the reticle.

Referring to FIG. 8F, the second photoresist layer 214 may be developed to form a second photoresist pattern 214a.

Referring to FIG. 8G, the substrate 110 may be etched using the second photoresist pattern 214a and the preliminary hardmask pattern 111a as etch masks. Thus, the substrate may be double-patterned with a line width of 20 nm. Then, the second photoresist pattern 214a and the preliminary hard mask pattern 111a may be removed.

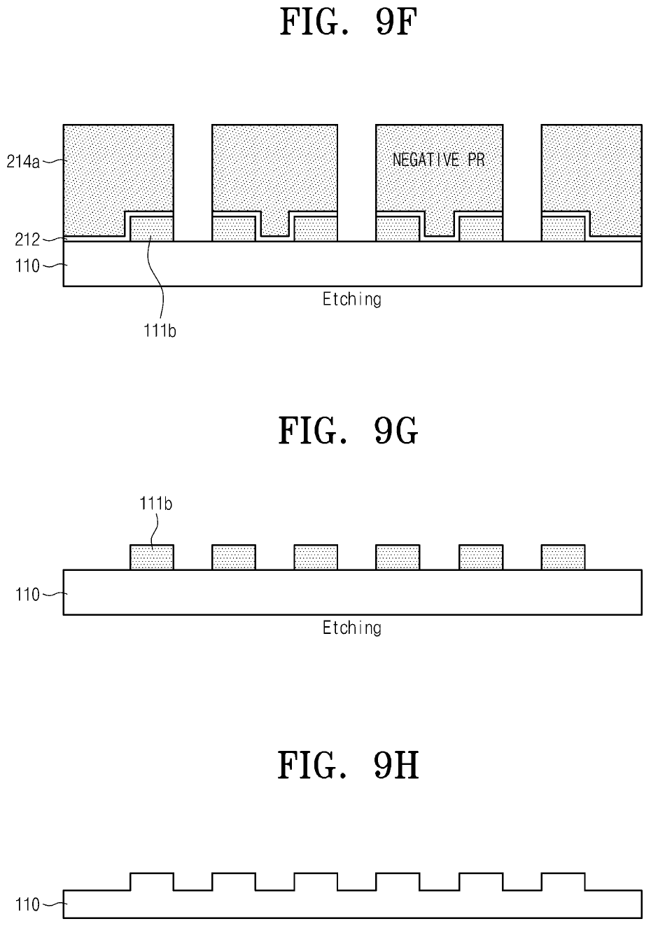

FIGS. 9A to 9H are diagrams illustrating a double patterning method according to an example embodiment of the present disclosure.

Referring to FIGS. 9A to 9H, a double patterning method according to an example embodiment may include forming a hardmask layer 111 on a substrate 110; forming a first photoresist layer 114 on the hardmask layer 111; performing first divisional exposure on the first photoresist layer 114 with first exposure energy 21, higher than or equal to threshold energy, using a reticle 116 having lines and spaces of a mask pattern and an exposure apparatus 120; shifting the reticle below the line width of the mask pattern and performing second divisional exposure on the first photoresist layer 114 with second exposure energy, higher than or equal to the threshold energy, using the reticle; developing the first photoresist layer 114s to form a first photoresist pattern 114a; etching the hardmask layer 111 using the first photoresist pattern 114a as a mask to form a preliminary hardmask pattern 111a; removing the first photoresist pattern 114a and then forming a second photoresist layer 214 on the preliminary hardmask pattern 111a; shifting the reticle relative to the preliminary hardmask pattern 111a by ½ of a pitch of the mask pattern and then performing third divisional exposure on the second photoresist layer 214 with third exposure energy, higher than or equal to the threshold energy, using the reticle 116 and the exposure apparatus 120; and shifting the reticle below the line width of the mask pattern and then performing fourth divisional exposure on the second photoresist layer 214 with fourth exposure energy, higher than or equal to the threshold energy, using the reticle.

Referring to FIG. 9A, the substrate 110 may be a semiconductor substrate. The substrate 110 may include an etch layer for etching. A hardmask layer 111 may be formed on the substrate 110. The hardmask layer 111 may be an amorphous carbon layer.

A bottom anti-reflect coating (BARC) 112 may be formed on the hardmask layer. The bottom anti-reflect coating 112 may be disposed below the first photoresist layer 114 to reduce reflection of exposure beam.

A first photoresist layer 114 may be formed on the bottom anti-reflect coating 112. The first photoresist layer 114 may be a negative photoresist. The first photoresist layer 114 may have a thickness of 50 nm to 90 nm.

First divisional exposure may be performed on the first photoresist layer 114 with first exposure energy 21, higher than or equal to threshold energy, using the reticle 116 having lines and spaces of the mask pattern and the exposure apparatus 120.

The reticle may be shifted below the line width of the mask pattern, and second divisional exposure may be performed on the first photoresist layer with second exposure energy, higher than or equal to the threshold energy, using the reticle. A shift value (A) of the reticle may be 10% to 20% (4 nm to 8 nm) of the line width (40 nm) of the mask pattern.

Referring to FIG. 9B, the first photoresist layer may be developed to form a first photoresist pattern 114a. The development process may use spin development apparatus.

Referring to FIG. 9C, the hardmask layer 111 may be etched using the first photoresist pattern 114a as an etch mask to form a preliminary hard mask pattern 111a. The etching may be performed in an anisotropic plasma etching apparatus.

Referring to FIG. 9D, the first photoresist pattern 114a may be removed, and a second photoresist layer 214 may then be formed on the preliminary hard mask pattern 111a. A bottom reflective coating layer 212 may be disposed below the second photoresist layer 214. The second photoresist layer 214 may be formed of the same material and structure as the first photoresist layer 114.

The reticle 116 may be shifted by ½ of a pitch of the mask pattern with respect to the preliminary hard mask pattern 111a, and third divisional exposure may then be performed on the second photoresist layer 241 with third exposure energy 21′, higher than or equal to the threshold energy, using the reticle 116 and the exposure apparatus 120.

The reticle 216 may be shifted below the line width of the mask pattern, and fourth divisional exposure may be performed on the second photoresist layer 214 with fourth exposure energy 22′, higher than or equal to the threshold energy, using the reticle 216.

Referring to FIG. 9E, the second photoresist layer 214 may be developed to form a second photoresist pattern 214a.

Referring to FIG. 9F, the preliminary hardmask pattern 111a may be etched using the second photoresist pattern 214a as an etch mask to form a main hardmask pattern lib.

Referring to FIG. 9G, the second photoresist pattern 214a may be removed, and the substrate 110 may be etched using the main hardmask pattern 111b as an etch mask. The substrate may be double-patterned with a linewidth of 20 nm.

Referring to FIG. 9H, the main hardmask pattern 111b may be removed.

As set forth above, the patterning method according to an example embodiment may form a pattern of 38 nm or less, which is a resolution limit of an ArF immersion apparatus.

The patterning method according to an example embodiment may form a line pattern of the level of 20 nm using an ArF immersion apparatus.

The patterning method according to an example embodiment may form a line at the level of 20 nm and a space pattern of the level of 20 nm using an ArF immersion apparatus.

Although the present disclosure and its advantages have been described in detail, it should be understood that various changes, substitutions and alterations can be made herein without departing from the spirit and scope of the disclosure as defined by the following claims.

What is claimed is:

1. A patterning method comprising:
forming a first photoresist layer on a substrate;
performing first divisional exposure on the first photoresist layer with first exposure energy, higher than or equal to threshold energy, using a reticle having lines and spaces of a mask pattern and an exposure apparatus; and
shifting the reticle below a line width of the mask pattern and performing second divisional exposure on the first photoresist layer with second exposure energy, higher than or equal to the threshold energy, using the reticle to form a photoresist pattern,
wherein
a spatial distribution of the first exposure energy overlaps a spatial distribution of the second exposure energy.

2. The patterning method as set forth in claim 1, wherein
the first exposure energy is 125% to 155% of threshold energy.

3. The patterning method as set forth in claim 1, wherein
a shift value of the reticle is 10% to 20% of a line width of the mask pattern.

4. The patterning method as set forth in claim 1, wherein
the exposure apparatus is an ArF immersion apparatus,
the mask pattern has a line width of 40 nm, and
the mask pattern has a space width of 40 nm.

5. The patterning method as set forth in claim 1, further comprising:
developing the first photoresist layer to form a patterned first photo resist pattern,
wherein
the first photoresist pattern has a line width of less than 33 nm.

6. The patterning method as set forth in claim 5, wherein
the line width of the patterned first photoresist pattern is at a level of 20 nm, and
a space width of the patterned first photoresist pattern is at a level of 60 nm.

7. The patterning method as set forth in claim 1, further comprising:
developing the first photoresist layer to form a patterned first photoresist pattern,
wherein
an aspect ratio of a height of the first photoresist pattern to a line width of the first photoresist pattern is 4 or less.

8. The patterning method as set forth in claim 1, wherein
the first exposure energy is the same as the second exposure energy, and the first exposure energy is 143% of the threshold energy.

9. The patterning method as set forth in claim 1, further comprising:
developing the first photoresist layer to form a patterned first photoresist pattern,
wherein
the first exposure energy and the second exposure energy are higher than or equal to the threshold energy, and
a sum of the first exposure energy and the second exposure energy is 260% to 300% of the threshold energy.

10. A patterning method comprising:
forming a hardmask layer on a substrate;
forming a first photoresist layer on the hardmask layer;
performing first divisional exposure on the first photoresist layer with first exposure energy, higher than or equal to threshold energy, using a reticle having lines and spaces of a mask pattern and an exposure apparatus;
shifting the reticle below the line width of the mask pattern and performing second divisional exposure on the first photoresist layer with second exposure energy, higher than or equal to the threshold energy, using the reticle;
developing the first photoresist layer to form a first photoresist pattern;
etching the hardmask layer using the first photoresist pattern as a mask to form a preliminary hardmask pattern;
removing the first photoresist pattern and then forming a second photoresist layer on the preliminary hardmask pattern;
shifting the reticle relative to the preliminary hardmask pattern by ½ of a pitch of the mask pattern and then performing third divisional exposure on the second photoresist layer with third exposure energy, higher than or equal to the threshold energy, using the reticle and the exposure apparatus; and
shifting the reticle below the line width of the mask pattern and then performing fourth divisional exposure on the second photoresist layer with fourth exposure energy, higher than or equal to the threshold energy, using the reticle.

11. The patterning method as set forth in claim 10, further comprising:
developing the second photoresist layer to form a second photoresist pattern; and
etching the substrate using the second photoresist pattern and the preliminary hardmask pattern as etch masks.

12. The patterning method as set forth in claim 10, further comprising:
developing the second photoresist layer to form a second photoresist pattern;
etching the preliminary hardmask pattern using the second photoresist pattern as an etch mask to form a main hardmask pattern; and
removing the second photoresist pattern and then etching the substrate using the main hardmask pattern as an etch mask.
